(19) United States
(12) Patent Application Publication
(10) Pub. No.: US 2008/0073111 A1
(43) Pub. Date: Mar. 27, 2008

(54) Single Package Multiple Component Array With Ball Grid Array Mounting and Contact Interface

(75) Inventor: Elmer Albert Wolff, Richardson, TX (US)

Correspondence Address: CHALKER FLORES, LLP, 2711 LBJ FRWY, Suite 1036, DALLAS, TX, 75234, US

(73) Assignee: VLSIP TECHNOLOGIES, INC., Richardson, TX (US)

(21) Appl. No.: 11/738,280

(22) Filed: Apr. 20, 2007

Related U.S. Application Data
(60) Provisional application No. 60/847,059, filed on Sep. 25, 2006.

(51) Int. Cl. H05K 1/16

(52) U.S. Cl. 174/260; 361/301.4; 438/396

(57) ABSTRACT

The present invention includes an apparatus and methods of making a modular system that includes a substrate having two or more conductive pads; one or more first surface mounted electronic components being electrically connected to the conductive pads; and one or more second surface mounted electronic components electrically connected in parallel with the first by solder bonding to the first surface mounted electronic component.

### CROSS-REFERENCE TO RELATED APPLICATIONS

This application claims priority to U.S. Provisional Patent Application Ser. No. 60/847,059, file Sep. 25, 2006, the entire contents of which are incorporated herein by reference.

### TECHNICAL FIELD OF THE INVENTION

The present invention relates in general to the field of component interconnects, and more particularly, to an apparatus and method for making a single package, multiple component array using ball grid array mounting and contact interface(s).

### BACKGROUND OF THE INVENTION

Without limiting the scope of the invention, its background is described in connection with electronic interconnects.

One example of a capacitor solder ball structure is taught in U.S. Pat. No. 6,657,133, issued to Chee for a ball grid array (BGA) chip capacitor structure. Briefly, a BGA-type capacitor structure is shown that includes a conventional chip capacitor mounted on the upper surface of an inexpensive substrate, and having solder balls mounted on a lower surface of the substrate. Lands that are required to mount the chip capacitor are formed on the substrate and are offset from the surface of a printed circuit board (PCB) by the solder balls. The substrate can be a thin sheet of polyimide tape that is etched or perforated to provide holes through which the solder balls contact the lands used to mount the chip capacitor. An assembly incorporating the BGA capacitor structure includes a PCB having an array of metal vias extending between opposing upper and lower surfaces, a BGA IC mounted on the upper surface and soldered to first ends of the metal vias. The capacitor structures are soldered to contact pads formed on the lower surface of the PCB.

Yet another example is taught in U.S. Pat. No. 6,058,004, issued to Duva, et al., which teach a unitized discrete electronic component arrays. Briefly, unitized discrete electronic component array is taught that is surface mountable as a unit on a printed circuit board comprising a plurality of discrete electronic components physically secured to one another by an adhesive. The adhesive is a non-conducting high temperature resistant epoxy, polyimide or glass. The electronic components are capacitors, resistors or inductors, or combinations thereof.

### SUMMARY OF THE INVENTION

The present invention includes components, systems and methods for the formation of electronic components that includes a substrate with two or more conductive pads, one or more first surface mounted electronic components being electrically connected to the conductive pads forming a single layer modular system. A multilayer modular system is formed by adding one or more second surface mounted electronic components electrically connected with the first by bonding to the first surface mounted electronic component. In one embodiment, the second surface mounted electronic component is located adjacent, side by side, of the first surface mounted electronic component forming a row of N width, or above the first surface forming a stack of N components high. In another embodiment, the first and second surface mounted electronic component form single, double, or n levels of electronic component to form an array and/or either a single, double, or n levels of electronic component to form an array. The system may also include a non-conductive housing, one of the conductive pads, a sensor connected to one of the conductive pads and/or one or more integrated circuits.

In one specific example, the present invention includes a system that has an electronic circuits connected to one of the conductive pads, a sensor connected to the second conductive pad, wherein the electronic components in the array to connect and protect the electronic circuits from random extraneous signal inputs from the sensors. In another specific example, the system includes an electronic circuit connected to one of the conductive pads, a sensor connected to the second conductive pad and the electronic component connects and protects the integrated circuit from unwanted extraneous signals from the sensor and the values of the first and second electronic component are typically but not limited to 0.0001, 0.001, 0.01, 0.1, 1, 2, 5, 10, 20, 30, 40, 50, μFarad capacitors. An example of the uses for the array system is a biosensor connected to the first conductive pad and a electronic medical device either implanted or human carry device, illustrated by and not limited to defibrillator, pacemaker, neurostimulation or recording devices. The first, second or both electronic components may be selected from the group consisting of but not limited to capacitors, switches, resistors, thermistors, transistors, optoelectronic transceivers and diodes.

The present invention also includes a modular capacitor array having a substrate comprising a two or more pairs of conductive pads on the substrate, two or more first surface mounted capacitors being electrically connected, each to one of the pairs of conductive pads and two or more second surface mounted capacitor electrically connected in parallel with the first by bonding, wherein the first and second surface mounted capacitors double the capacitance of the capacitors, wherein the array comprises single, double, or n levels of capacitors. The array may also include a non-conductive housing, an integrated circuit connected to one of the conductive pads and/or a sensor connected to one of the conductive pads. The array may be either a single, double, or n levels of capacitors to form an array. The array may be part of an overall electronic package or device that also includes an integrated circuit connected to one of the conductive pads, a sensor connected to the second conductive pad and the capacitors in the array protect the integrated circuits from random extraneous signal inputs from the sensors. Alternatively, the device may include an integrated circuit or electronic circuit connected to one of the conductive pads, a sensor connected to the second conductive pad and the capacitors protect the integrated circuit end the electronic circuit from unwanted extraneous signals from the sensor and the values of the first and second capacitors are typically but not limited to 0.0001, 0.001, 0.01, 0.1, 1, 2, 5, 10, 20, 30, 40, 50, μFarad capacitors, wherein a biosensor is connected to the first or second conductive pad.

The present invention also includes a method for reducing the substrate footprint of a capacitor array by electrically connecting one or more first surface mounted capacitors on a pair of conductive pads on a substrate and electrically connecting one or more second surface mounted capacitor with the first in parallel by connecting to the first surface mounted capacitor, wherein the first and second surface mounted capacitors sum up to the total capacitance of the final capacitors.

### BRIEF DESCRIPTION OF THE DRAWINGS

For a more complete understanding of the features and advantages of the present invention, reference is now made to the detailed description of the invention along with the accompanying figures and in which:

FIG. 1 is an isometric view of an electronic package of the present invention;

FIG. 2 shows a top view of an electronic package

FIG. 3 is a side view of the electronic component array

FIGS. 4 and 5 are a top and a cross-sectional view of an electronic component array; and

FIGS. 6A to 6F are side views of one method for assembling a stacked component array of the present invention.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not delimit the invention, except as outlined in the claims.

The present invention is related to an arrangement of two or more electrical components in a multi component assembly. As defined herein, the term “multi component” refers to a set of two or more electrical components (e.g., capacitors, switches, resistors, thermistors, transceivers, transistors, optoelectronic transceivers, diodes, and the like) that are in close proximity and electrically connected together so that they function as a unit. Commonly, they are also physically and electrically coupled by a common solder ball and assembled on a substrate or board, and encapsulated in a package. In one embodiment of the invention, the electrical components are dissimilar relative to their size, design, and function; in another embodiment they are identical. In yet another embodiment of the invention the assembly method is the same for the electrical components; in another embodiment they may differ from component to component.

The electrical components may be assembled onto a substrate or carrier, e.g., a standard printed circuit board constructed from a material such as FR-4 which is available from, for example, Motorola Inc., U.S.A. FR-4 is an epoxy resin reinforced with a woven glass cloth. In selecting the material for carrier, one skilled in the art will recognize that four parameters should be considered, namely, thickness, dielectric constant, glass transition temperature and the coefficient of thermal expansion. Other materials for use with the carrier are high temperature epoxies such as FR-5 or BT-resin, available from Allied Signal, U.S.A. or Mitsubishi, Japan, which may also contain a reinforcing fiberglass mesh to increase the tensile strength of the material.

The thickness of the carrier is also dependent on the number of layers required and the amount of reinforcement used in a given layer. The reinforcing glass cloth can range in thickness from 2 mil per sheet (type 106) to about 8 mil per sheet (type 7628). Dielectric constant is determined by a combination of the resin used and the thickness and type of reinforcement used. Standard FR-4 has a dielectric constant of about 4.5. This constant can be reduced to about 3 by replacing the epoxy resin with a cyanate ester resin. The greater the thickness, however, the greater the problems associated with thickness control, rough surfaces, excessive drill wear and poor resin refill.

The temperature at which a resin changes from a glass-like state into a “rubbery” state is generally designated as Tg. Standard FR-4 is made with a bifunctionally polymerizing epoxy that has a Tg of about 110° C. Higher Tg temperatures, such as 125-150° C. may be withstood by using a tetrafunctional epoxy. For higher Tg values, in the range of 150 to 200° C., a cyanate ester:epoxy blend can be used. Additionally, polyimides provide for printed circuit boards having a Tg above 250° C. The coefficient of thermal expansion for FR-4 is about 16 ppm/° C.

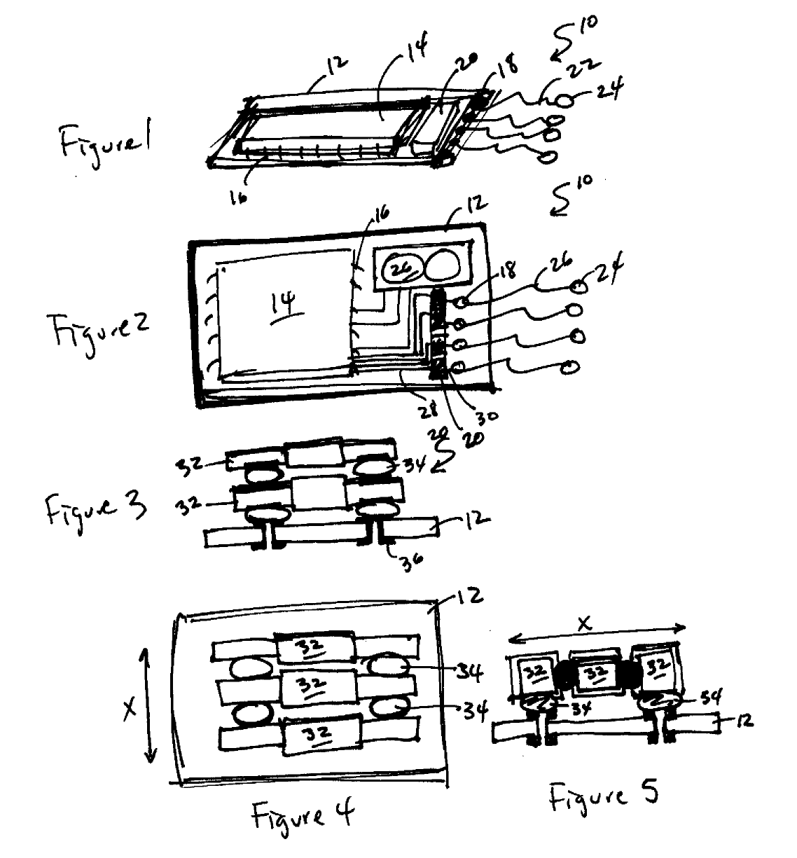

FIG. 1 is an isometric view of an electronic package 10 that is shown with a printed circuit board 12, an integrated circuit 14, wire interconnects 16 and pads 18. Adjacent to and between the integrated circuit 14 and the pads 18 is an electronic component array 20 that is connected to the printed circuit board 12 by solder balls (not depicted). Connected to the pads 18 are wire leads 22 that terminate, in this example, in a sensor 24. In FIG. 1, the array is electronic component array 20 is physically and electrically connected between the integrated circuit 14 and the sensors 24. The electronic component array 20 in this example may be an array of capacitors that serve to protect the integrated circuit 14 from electrical, thermal, mechanical or other discharges that may enter the sensors 24 and travel toward the integrated circuit 14 (or vice versa).

FIG. 2 shows a top view of an electronic package 10 that is shown with a printed circuit board 12, an integrated circuit 14, wire interconnects 16 and pads 18. Also shown in this view is a power source 26, depicted in this example as a pair of low-profile batteries. Adjacent to and between the integrated circuit 14 and the pads 18 is an electronic component array 20 that is connected to the printed circuit board 12 by solder balls (not depicted) via printed wires 28 and 30. Connected to the pads 18 are wire leads 22 that terminate, in this example, in a sensor 24. As depicted in FIG. 1, the array is electronic component array 20 is physically and electrically connected between the integrated circuit 14 and the sensors 24.

FIG. 3 is a side view of the electronic component array 20, which shows in this embodiment a stacked version of the electronic component array 20 that includes two separate electronic components 32. The electronic components 32 may be capacitors, switches, resistors, thermistors, transceivers, transistors, optoelectronic transceivers, diodes, and the like. In FIG. 3, the electronic components 32 are connected to the printed circuit board 12 via solder balls 34, depicted in this side view as located between the electronic components 32 and the printed circuit board 12 where they connect electrically to vias 36.

In FIGS. 4 and 5 are a top (FIG. 4) and a cross-sectional view (FIG. 5) of an electronic components array 20 where the electronic components 32 are not stacked by side-by-side. Of course, the electronic components 32 may be both stacked and side-by-side, depending on the particular needs for space and electrical effect of the electronic components 32 as will be know to those of skill in the art. The electronic components 32 may be connected in series or in parallel. In FIG. 4, the solder balls 34 connect the electronic components 32 (in this case 3 side-by-side, electrically connected electronic components 32 are shown) along an axis X. FIG. 5 shows the three electronic components 32 also along the axis X and further connected to the printed circuit board 20 by solder balls 34.

Solder balls 34 may also connect one or more integrated circuit packages 14 to a printed circuit board 20 using solder balls (not depicted) or the electronic components 32 may be connected to the printed circuit board 20 by wire bonding (also not depicted). The electronic components 32 and/or the electronic component array 20 may be attached to other components, a mother, sister board, in a flip-chip configuration or to one or more arrays of electronic components 32. The number of electronic components 32 that are stacked will depend on, e.g., the electrical circuit, space and/or contact requirements of the electronic component array 20, however, in one embodiment of the present invention the number of electronic components 32 is two, three, four, five, six, seven, eight, nine, ten, eleven or twelve. The electronic component array 20 may also be connected to other electronic component arrays 20.

The electronic component array 20 will often be provided as an assembly that is encapsulated as described below. The term “assembly” refers to the assembled components prior to encapsulation. The assembly is basically, the electronic components 32 are connected to the printed circuit board 12 via solder balls 34, depicted in this side view as located between the electronic components 32 and the printed circuit board 12 where they connect electrically to vias 36.

The solder bonding process may begin after one or more electronic components 32 has been solder bonded to printed circuit board 12. Electronic components 32 and printed circuit board 12 are then positioned on a heated pedestal to raise the temperature of the combined unit. The solder bonding 80 and solder balls 150 used to create the electronic components 32 for use with the present invention may be attached using conventional solder reflow systems. For example, a vapor phase solder reflow system may be used, which condenses vapor to surround the integrated circuit package 30 and the printed circuit board 12 with a cloud of steam. A liquid, such as a nonchlorinated (non CFC) fluorocarbon is first heated with enough energy to form a vapor and to sustain a vapor cloud. When the electronic components 32 are then passed through the vapor, the vaporized liquid condenses thereon and gives off the latent heat of vaporization. This energy is then transferred to the electronic components 32. As long as the electronic components 32 remains in the vapor, the vapor continues to give off energy at a repeatable fixed rate and temperature, until the electronic components 32 reaches the temperature of the vapor. Likewise the entire assembly of integrated circuit packages may be introduced into the solder melting chamber after being stacked.

Nonchlorinated fluorocarbon has the advantage that it is extremely thermally stable, colorless, odorless and nonflammable. In addition, it has a low toxicity, low surface temperature, low boiling point, and low heat of vaporization. Because the fluid form of the non-chlorinated fluorocarbon is inert, it does not react with fluxes or component materials, nor does it absorb oxygen or other gases that cause reactions during the solder reflow. Most commercially available fluorocarbons used Lor vapor phase reflow are formulated to vaporize at precisely stable reflow temperatures Lor different solder materials, as will be known to those skilled in the art. The vaporization temperature will depend on the solder type being used. A brief list of the non-chlorinated fluorocarbons that are used as vapor fluids is shown below.

Alternatively, infrared or radiant heated solder reflow may be used. In such a system each component of the soldering system is directly exposed to radiation from a heating element. Heat from the radiant energy element is absorbed by the different components according to its molecular structure, in this case the electronic components 32, the solder balls 34 and any other components.

Conventional radiant heat systems expose only the outer surfaces of the components to the radiant heat, which may not reach interior areas as efficiently as with vapor saturated heating methods as described above. The present invention, however, is not affected by this typical problem because of the use of solder instead of leads or wire bonding. In fact, due to the reduced overall size, vapor phase solder reflow or radiant heated solder reflow may be effectively used with the present invention.

In one embodiment of the present invention eutectics having different melting temperatures may be used for the solder bonding and the solder balls 34. The factors used to determine the relative melting temperatures for the solder bonding and the solder balls 34 include, e.g., the relative operating temperature and the amount of encapsulation, if any, of the electronic components 32. Also a factor is the total number of reflow steps to which the solder bonding and/or the solder balls 34 will be exposed. If the solder bonding and the solder balls 34 are exposed to the same number of heat reflow steps, as is the case where all the components are reflowed at the same time, then the same eutectic may be used. If one or the other component is exposed to one or more heat reflow steps prior to final assembly, then different eutectics may be chosen. For example, if the solder bonding is to occur before the solder balls 34 are attached, then a eutectic having a higher melting temperature may be chosen for the first heat reflow step in order to prevent a second melting of the solder bonding.

In some embodiments, the electronic component array 20 may be wire bonded to input/output contact pads on the printed circuit board 12 by bonding wire interconnects 16. Wire bonding begins heating the components on a heated pedestal to raise their temperature to between 170 and 300° C. A wire typically of gold, gold-beryllium alloy, other gold alloy, or copper, having a diameter typically ranging from 18 to 32 μm is strung through a heated capillary where the temperature usually ranges from 200 to 500° C. At the tip of the wire, a liquid ball is created using either a flame or a spark technique. The capillary is moved towards the chip bonding pad and the ball is pressed against the metallization of the bonding pad (typically aluminum, aluminum-copper alloy, or copper, between 0.5 and 1 μm thick). A combination of compression force and ultrasonic energy create the formation of gold-aluminum intermetallics and thus the strong metallurgical bond. In case of copper wire on copper pad, only metal interdiffusion takes place in order to generate the strong weld. Ball pitches of 75 to 50 μm can be achieved.

Moving the capillary in a predetermined and computer-controlled manner through the air will create a wire looping of exactly defined shape; for instance, recent technical advances allow the formation of rounded, trapezoidal, linear or looped paths. Finally, the capillary reaches the lead, is lowered to touch it with an imprint of the capillary, thus forming a metallurgical stitch bond. The lateral dimension of the stitch imprint is about three times the wire diameter; its exact shape depends on capillary wall thickness and footprint. Recent technical advances allow the formation of wire looping with a minimum length of bonding wire by moving the bonding capillary the shortest feasible distance to the lead. As a consequence, the looping of the wire can cross the silicon surface at a height of approximately 10 μm and high looping spans are no longer an issue. The wire is finally flamed off to release the capillary. The advantage of bonding wires is their tolerance to mechanical stress, which appears unavoidably in an assembly of parts having different coefficients of thermal expansion, when the assembly operates through temperature cycles. However, bonding wires have to be protected against mechanical damage, preferably by a molded package; also, their contribution to parasitic inductance has to be accounted for in the circuit design.

As used herein, the term solder “ball” includes solder that is generally spherical, semispherical, half-dome, truncated cone, or generally bump, or a cylinder with straight, concave or convex outlines. The exact shape is a function of the deposition technique (such as evaporation, plating, or prefabricated units) and reflow technique (such as infrared or radiant heat), and the material composition. Generally, a mixture of lead and tin is used; other material include indium or indium/tin alloys. When used in conjunction with wire bonding, the melting temperature of the solder ball will be lower than the wire bonding temperature used for bonding, because the wire bonding operation is commonly performed before the solder reflow attachment of component. Several methods are available to achieve consistency of geometrical shape by controlling amount of material and uniformity of reflow temperature. Typically, the diameter of the solder balls ranges from 0.1 to 0.5 mm.

In order to insure reliable attachment of the solder to the leads (as well as to the chip contact pads), preparations have to be taken for achieving proper wetting of the lead surfaces. In those lead surface portions which are involved in solder attachment, sequential layers of nickel and a noble metal are often deposited over the base metal of the printed circuit board 12. Palladium and gold are often the best choice for the solder ball contacts, but are not required. The contact pads may be covered by layers of a refractory metal (such as chromium, molybdenum, titanium tungsten, or titanium/tungsten alloy) and a noble metal (such as palladium, gold, platinum or platinum-rich alloy, silver or silver alloy). Good wetting is achieved because at reflow temperature, the thin palladium layer is dissolved into the solder so that is attaches reliably to the clean nickel underneath.

The electronic package 10 of the present invention will often, but not always, be encapsulated. It is advantageous to encapsulate the electronic package 10 into a molded package. Depending on the specific needs for the package, e.g., environmental exposure, temperature, potential exposure to liquids, pH, humidity, corrosive agents, etc., the encapsulant may be selected to maximize protection to the electronic package 10 while at the same time being compatible with the location for use. During the encapsulation process, transfer molding processes are used to control viscosity, pressure, time, and temperature to minimize the effect of the encapsulant on the bonding of the electronic package 10. For very thin profile packages, materials having very low viscosity and high adhesion are often used to make sure that the encapsulant permeates the entire electronic package 10 and its components. Suitable epoxy-based thermoset resins or silicone-based elastomerics are commercially available from Sin Etsu Chemical Corporation, Japan, or Kuala Lumpur, Malaysia, or from Sumitomo Bakelite Corporation, Japan, or Singapore, Singapore. These materials also contain the appropriate fillers needed for shifting the coefficient of thermal expansion closer to that of silicon, and for enhancing the strength and flexibility of the molding material after curing.

The molding temperature (usually from 140 to 220° C.) can be selected such that is lower than the reflow temperature of solder balls 34. Even minute spaces, for instance around and between the solder balls 34, can be reliably filled with molding material. Voids or other cosmetic defects, are eliminated, and mechanical stress on the solder joints is minimized by this “underfilling” process.

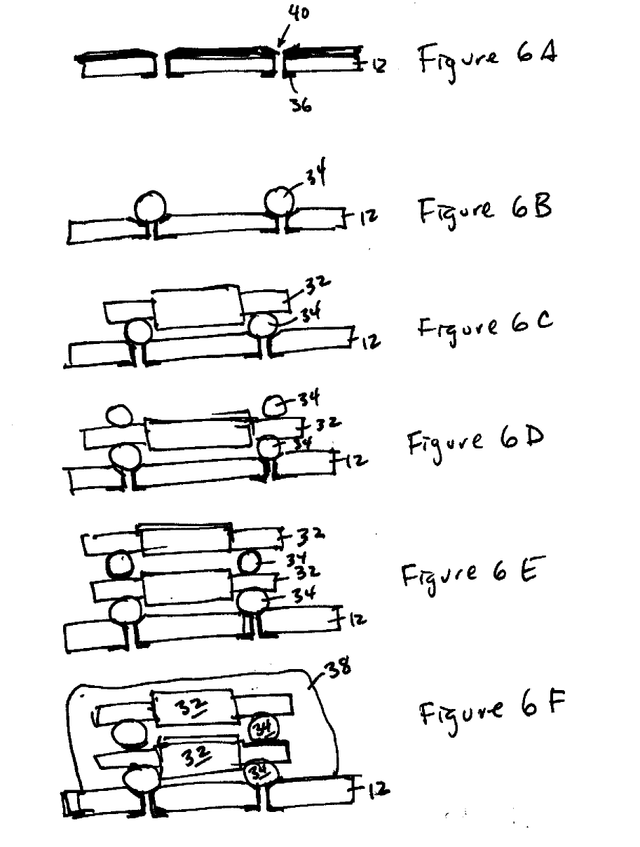

FIGS. 6A to 6F are side views of one method for assembling a stacked component array of the present invention. The array is formed by the placing, adjacent to the electrical components 32 depicted, one or more additional electrical components 32 stacks (not depicted). In FIG. 6A, indents 40 are shown pressed into the printed circuit board 12. Next, in FIG. 6B, solder balls 34 are placing into the undulations 40, followed by the positioning and solder bonding of the electronic component 32 on the solder balls 34 (FIG. 6C). FIG. 6D shows the addition of the next solder balls 34 followed, in FIG. 6E by the addition of the next electronic component 32. Finally, in FIG. 6F the entire electronic package is coated with an encapsulant 38.

The depths, rims and contours of the indents are suitable for positioning one solder ball into each indent. In this fashion, the positioning of solder balls and of chips carrying solder balls relative to the leads can be greatly facilitated; escapes and poor placements are practically eliminated, thus increasing production throughput and yield. The diameters of the solder balls range from 100 to 500 μm; as described above, they comprise lead/tin alloys chosen for a melting temperature consistent with the multi-component assembly process.

In order to generate the appropriate undulating pattern, the thickness of the starting material of the printed circuit board 12 and the diameter of the solder balls are correlated. Dependent on the ball diameter range to be processed, the indents are pressed into both lead surfaces; care is taken that the contours remain safely within the elastic regime of the printed circuit board 12; overstretch or microcracks of the printed circuit board 12 are avoided. The rims of the indents are not critical; they may be relatively sharp, as shown in FIGS. 6A to 6F, or more rounded. As an empirical rule, the lead width should preferably be equal to or larger than the solder ball feature size, and the space between adjacent leads should be equal to or larger than half of the solder ball feature size. If the available space is smaller, the indents can be placed in a staggered pattern.

It is essential to prepare the surfaces of the undulating lead tips shown in FIGS. 6A to 6F metallurgically such that wetting of the leads during reflow of the solder balls is promoted. The method is described above in conjunction with FIG. 6A to 6F. In essence, sequential layers of nickel and a noble metal such as palladium are deposited over the base metal of the leads tips, commonly copper (or Alloy).

The electronic components 32 may be electronic components such as individual electrical components or even chips of identical types or of different types. The electrical components may comprise silicon, silicon germanium or gallium arsenide, or any other semiconductor material used in electronic device production. In particular, the electronic components may be identical or different integrated circuit types.

Even if solder assembled chips are mechanically not as sensitive as wire bonded chips, it is advantageous to encapsulate the assembly in a molded package. The molding compound acts as “underfilling” material for the solder connections, thus minimizing thermomechanical stress on the solder joints during device operation.

Thus, it is apparent that there has been provided, in accordance with the present invention, a ball grid array package and method that satisfy the advantages set forth above. Also, the number and arrangement of grounding leads or solder balls coupled to the printed circuit board 12 and/or the electronic components 32 may be provided in any arrangement without departing from the present invention. Furthermore, the direct connections illustrated herein could be altered by one skilled in the art such that two or more electronic components 32 or elements are merely coupled to one another through an intermediate device or devices, without being directly connected, while still achieving the desired results demonstrated by the present invention.

It is contemplated that any embodiment discussed in this specification can be implemented with respect to any method, kit, reagent, or composition of the invention, and vice versa. Furthermore, compositions of the invention can be used to achieve methods of the invention.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, MB, BBC, AAABCCCC, CBBAAA, CABABB, and so forth. The skilled artisan will understand that typically there is no limit on the number of items or terms in any combination, unless otherwise apparent from the context.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

1. A modular system comprising:
a substrate comprising two or more conductive pads;
one or more first surface mounted electronic components being electrically connected to the conductive pads; and
one or more second surface mounted electronic components electrically connected in parallel with the first by solder bonding to the first surface mounted electronic component.

2. The system of claim 1, wherein the second surface mounted electronic component is located adjacent the first surface mounted electronic component, opposite the substrate, adjacent on either side of the first surface mounted electronic component, or adjacent and above the first adjacent the first surface mounted electronic component.

3. The system of claim 1, wherein the first and second surface mounted electronic component form single, double, or n levels of electronic component to form an array.

4. The system of claim 1, wherein the system comprises either a single, double, or n levels of electronic component to form an array.

5. The system of claim 1, wherein the system further comprises a non-conductive housing.

6. The system of claim 1, wherein the system further comprises an integrated circuit connected to one of the conductive pads.

7. The system of claim 1, wherein the system further comprises a sensor connected to one of the conductive pads.

8. The system of claim 1, wherein the system further comprises an integrated circuits connected to one of the conductive pads, a sensor connected to the second conductive pad, wherein the electronic components in the array protect the integrated circuits from random extraneous signal inputs from the sensors.

9. The system of claim 1, wherein the system further comprises an integrated circuit connected to one of the conductive pads, a sensor connected to the second conductive pad and the electronic component protects the integrated circuit from unwanted extraneous signals from the sensor and the values of the first and second electronic component are typically but not limited to 0.0001, 0.001, 0.01, 0.1, 1, 2, 5, 10, 20, 30, 40, 50, μFarad capacitors.

10. The system of claim 1, wherein the system comprises a biosensor connected to the first conductive pad and a medical device either implanted or human carry device, illustrated by and not limited to defibrillator, pacemaker, neurostimulation or recording devices.

11. The system of claim 1, wherein the first, second or both electronic components are selected from the group consisting of capacitors, switches, resistors, thermistors, transceivers, transistors, optoelectronic transceivers and diodes.

12. A modular capacitor array comprising:
substrate comprising a two or more pairs of conductive pads on the substrate;
two or more first surface mounted capacitors being electrically connected, each to one of the pairs of conductive pads; and
two or more second surface mounted capacitor electrically connected in parallel with the first by solder bonding, wherein the first and second surface mounted capacitors double the capacitance of the capacitors, wherein the array comprises single, double, or n levels of capacitors.

13. The array of claim 12, wherein the array further comprises a non-conductive housing.

14. The array of claim 12, wherein the array further comprises an integrated circuit connected to one of the conductive pads.

15. The array of claim 12, wherein the array further comprises a sensor connected to one of the conductive pads.

16. The capacitor system of claim 1, wherein the array comprises either a single, double, or n levels of capacitors to form an array.

17. The array of claim 12, wherein the array further comprises an integrated circuit connected to one of the conductive pads, a sensor connected to the second conductive pad and the capacitors in the array protect the integrated circuits from random extraneous signal inputs from the sensors.

18. The array of claim 12, wherein the system further comprises an integrated circuit connected to one of the conductive pads, a sensor connected to the second conductive pad and the capacitors protect the integrated circuit from unwanted extraneous signals from the sensor and the values of the first and second capacitors are typically but not limited to 0.0001, 0.001, 0.01, 0.1, 1, 2, 5, 10, 20, 30, 40, 50, μFarad capacitors.

19. The array of claim 12, wherein the system comprises a biosensor connected to the first or second conductive pad.

20. A method for reducing the footprint of a capacitor array comprising:
electrically connecting one or more first surface mounted capacitors on a pair of conductive pads on a substrate; and
electrically connecting one or more second surface mounted capacitor with the first in parallel by solder bonding to the first surface mounted capacitor, wherein the first and second surface mounted capacitors double the capacitance of the capacitors.

21. The method of claim 20, wherein the array comprises either a single, double, or n levels of capacitors to form an array.

22. The method of claim 20, wherein the array is further encased in a non-conductive polymer.

23. The method of claim 20, wherein the array further comprises an integrated circuit connected to one of the conductive pads.

24. The method of claim 20, wherein the array further comprises a sensor connected to one of the conductive pads.

25. The method of claim 20, wherein the array further comprises an integrated circuit connected to one of the conductive pads, a sensor connected to the second conductive pad and the capacitors in the array protect the integrated circuits from random extraneous signal inputs from the sensors.

26. The method of claim 20, wherein the system further comprises an integrated circuit connected to one of the conductive pads, a sensor connected to the second conductive pad and the capacitors protect the integrated circuit from unwanted extraneous signals from the sensor and the values of the first and second capacitors are typically but not limited to 0.0001, 0.001, 0.01, 0.1, 1, 2, 5, 10, 20, 30, 40, 50, μFarad capacitors.

27. The method of claim 20, wherein the system comprises a biosensor connected to the first or second conductive pad.
